(19) United States
(12) Patent Application Publication
(10) Pub. No.: US 2005/0101041 A1
(43) Pub. Date: May 12, 2005

(54) Method of forming thin film

(75) Inventor: Hirofumi Kubota, Tsurugashima-shi (JP)

Correspondence Address: NIXON & VANDERHYE, PC, 1100 N GLEBE ROAD, 8TH FLOOR, ARLINGTON, VA, 22201-4714, US

(73) Assignee: PIONEER CORPORATION, Tokyo-to (JP)

(21) Appl. No.: 10/980,806

(22) Filed: Nov. 4, 2004

(30) Foreign Application Priority Data
Nov. 11, 2003 (JP) P2003-381755

(51) Int. Cl. H01L 21/00; H01L 21/84

(52) U.S. Cl. 438/22; 438/29

(57) ABSTRACT

A method of forming a thin film capable of forming a thin film of uniform thickness in a predetermined part without using any mask even in the case where there exist a part on which a thin film is formed and a part on which no thin film is formed is provided. Wettability of the surface of the part on which no thin film is formed is made lower than wettability of the surface of the part on which the thin film is formed.

### BACKGROUND OF THE INVENTION

1. Field of the Invention

The present invention relates to a method of forming a thin film.

2. Description of the Related Art

Formation of a thin film in a predetermined area of a substrate (that is, the part on which a thin film should be formed) has been conventionally practiced in various fields and various methods such as a printing method, spray method using a mask or spin coat method have been developed therefor.

For example, concerning an organic EL element, there has been a study on formation of a polymer hole injection layer on a pixel part (on a transparent electrode) to improve the characteristics of the organic EL element (Y. Sato, et al., Interface and Material Considerations of OLEDs, Proc. SPLE, Vol. 3797, Page 198, 1999).

However, when an attempt is made to form a polymer hole injection layer in the pixel part of the organic EL element according to a printing method or spray method using a mask, etc., while it is relatively easy to form a thin film only in a part where the polymer hole injection layer should be formed, that is, only in the pixel part, it is difficult to make uniform the thickness of the formed film and the use of a mask may result in a problem that debris is produced when the mask is removed.

On the other hand, when an attempt is made to form a polymer hole injection layer using a spin coat method, while it is relatively easy to make the film thickness uniform, it is extremely difficult to form a film only in the pixel part.

The present invention has been implemented in view of these problems and it is an example of objects of the present invention to provide a method of forming a thin film capable of forming a thin film of uniform thickness in a predetermined area without using any mask, etc., even when there exist a part on which a thin film is formed and a part on which no thin film is formed as in the case of a polymer hole injection layer of an organic EL element.

### SUMMARY OF THE INVENTION

In order to attain the problems described above, the embodiment according to claim 1 is a method of forming a thin film in a case where there exist a part on which a thin film is formed and a part on which no thin film is formed, the method comprising a wettability controlling step of making wettability of the surface of the part on which no thin film is formed lower than wettability of the surface of the part on which the thin film is formed.

### BRIEF DESCRIPTION OF THE DRAWINGS

FIG. 1(a) is a schematic front view of an organic EL element and FIG. 1(b) is a schematic cross-sectional view of the organic EL element shown in FIG. 1(a); and

FIG. 2 is a flow chart illustrating steps when the method of the present invention is applied to a case where a polymer hole injection layer of the organic EL element 10 shown in FIG. 1 is formed.

### DESCRIPTION OF THE PREFERRED EMBODIMENTS

The method of forming a thin film according to the present invention will be explained more specifically below.

The method of forming a thin film according to the present invention is a method of forming a thin film, which is particularly effective when there exist a part on which a thin film is formed and a part on which no thin film is formed and characterized by comprising a wettability controlling step in which wettability of the surface of a part on which no thin film is formed is made lower than wettability of the surface of a part on which the thin film is formed.

According to such a method of forming a thin film, even if there exist a part on which a thin film is formed and a part on which no thin film is formed, providing the wettability controlling step makes wettability of the surface of the part on which no thin film is formed lower than wettability of the other area (that is, the part on which a thin film is formed). Therefore, even if a thin film material is applied to the entire area without making any distinction between these areas, the thin film material applied to the relevant area is naturally repelled and moved to the part on which the thin film is formed or in the case of a spin coat, the thin film material is repelled outside the part on which the thin film is not formed with the result that there is no need to use any mask when the thin film material is applied. Furthermore, when the thin film material is applied, the thin film material can be applied indiscriminately without making any distinction between areas to which the thin film material is applied, and therefore it is also possible to improve the application efficiency and apply the thin film material uniformly.

The method of forming a thin film of the present invention will be explained taking a case where an organic EL element is manufactured as an example.

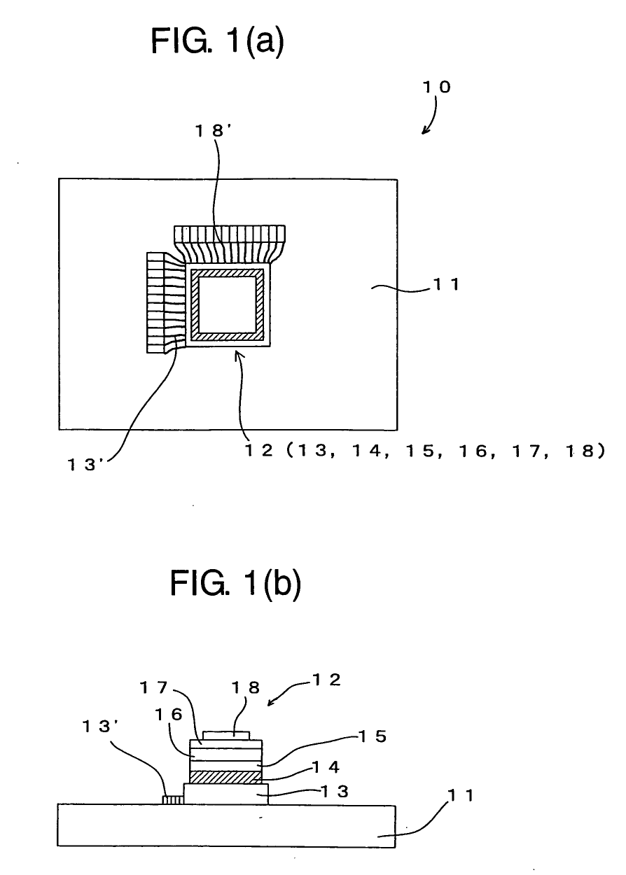

FIG. 1(a) is a schematic front view of an organic EL element and FIG. 1(b) is a schematic cross-sectional view of the organic EL element 10 shown in FIG. 1(a). As shown in FIG. 1, the organic EL element 10 has a structure that a pixel part 12 made up of a plurality of thin layers laminated one atop another on a substrate 11 and leading electrodes 13′, 18′ are disposed around the pixel part 12. Here, the pixel part 12 in the organic EL element 10 is a generic name of the parts forming an image such as a transparent electrode (anode) 13, a polymer hole injection layer 14, a hole transport layer 15, a light-emitting layer 16, an electron transport layer 17 and electrode (cathode) 18 laminated in order from the substrate 11. A case where a polymer hole injection layer of the pixel part of the organic EL element 10 is formed on the transparent electrode in particular will be explained below. That is, when the polymer hole injection layer 14 (that is, thin film) is formed on the pixel part 12 of the organic EL element 10 using the method of forming a thin film of the present invention, the transparent electrode 13 becomes the “part on which a thin film is formed” and the part other than the transparent electrode 13 such as the substrate 11 (including leading electrode 13′) becomes the “part on which no thin film is formed.”

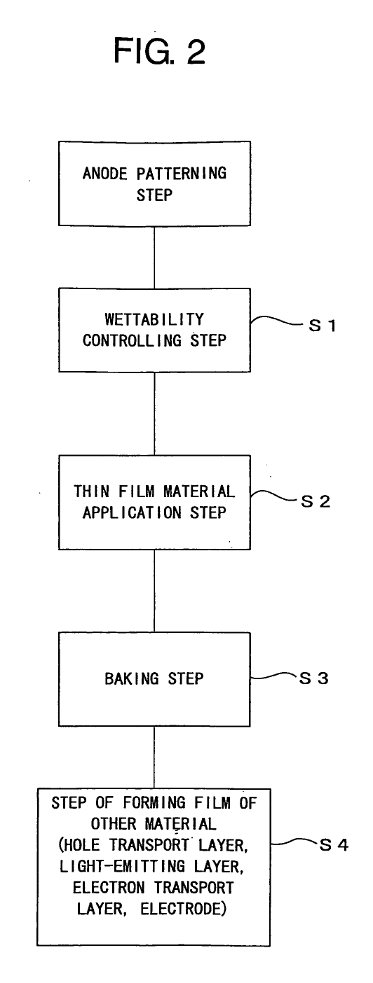

FIG. 2 is a flow chart illustrating steps when the method of the present invention is applied to a case where a polymer hole injection layer 14 of the organic EL element 10 shown in FIG. 1 is formed.

As shown in FIG. 2, an anode patterning step of forming a transparent electrode (anode) 13 and leading electrode 13′ on the transparent substrate 11 is performed first. The anode patterning step is not particularly limited and it is possible to use any publicly known method.

Next, a wettability controlling step S1 is performed on the transparent electrode 13 formed on the transparent substrate 11 in the anode patterning step.

This wettability controlling step S1 is a step for making wettability of the surface of the part on which no polymer hole injection layer is formed lower than wettability of the surface of the part on which the thin film is formed in order that when a polymer hole injection layer formation material is applied to the entire surface of the transparent substrate 11 on which the transparent electrode 13 is already formed in a thin film material application step S2 which will be described later, the polymer hole injection layer formation material applied to the surface of the part on which no polymer hole injection layer is formed (that is, substrate 11 or transparent electrode 13) is naturally repelled and the polymer hole injection layer formation material remains only on the surface of the part on which the polymer hole injection layer is formed (that is, the part which becomes the pixel part 12 thereafter). Therefore, in this step S1, it is only necessary to be able to control wettability of the surface on which the thin film is formed and wettability of the surface on which no thin film is formed to a degree that the aforementioned operation and effects are achieved in the thin film material application step S2 which will be described later and the specific method thereof will not be particularly limited and any method can be used.

A first method for controlling wettability of the surface of the part on which a thin film is formed and the part on which no thin film is formed (making wettability of the surface of the part on which no thin film is formed lower than wettability of the surface of the part on which a thin film is formed) is to apply fluoride processing to the surface of the part on which no thin film is formed, in other words, the part on which wettability is lowered to thereby replace the surface of the relevant part with fluorine. Fluorine replacement using such fluorine processing can provide the surface of the relevant part with water repellency.

For example, in the case where a polymer hole injection layer is only formed on the surface of the transparent electrode 13 of the organic EL element 10 shown in FIG. 1, the entire transparent substrate 11 on which the transparent substrate 13 is formed is subjected to UV ozone processing, etc., and the surface is cleaned. Then, the surface of the transparent substrate 13 is covered with a mask and subjected to processing with hydrofluoric acid (HF) in such a short time that the transparent substrate 13 is not corroded.

Applying such fluoride processing causes the surface of the part other than the masked transparent electrode 13 (surface of pixel part 12) is replaced with fluorine and it is possible to reduce wettability with respect to the polymer hole injection layer formation material applied to the relevant part thereafter.

Furthermore, a second method for controlling wettability of the surface not corresponding to the part on which a thin film is formed can be a method of forming a fluorine-based polymerization film on the surface of the part on which no thin film is formed, in other words, the surface of the part whose wettability is reduced. It is also possible to achieve the similar operation and effects as those in the first method by forming a fluorine-based polymerization film instead of fluorine replacement.

According to this second method, when the polymer hole injection layer 14 is only formed on the transparent electrode 13 of the organic EL element 10 (surface of the pixel part 12) as in the above described case, the entire transparent substrate 11 on which the transparent substrate 13 is formed is subjected to UV ozone processing, etc., and the surface is cleaned first, and then the surface of the transparent substrate 13 is covered with a mask and a film is formed using C₄F₈ gas and H₂ gas as raw materials and according to a plasma polymerization method (e.g., RF power: 0.59 W/cm² (13.56 MHz), pressure during film formation: 1.2 Torr, flow rate of C₄F₈ gas: 60 sccm, flow rate of H₂ gas: 50 sccm)

Forming such a fluorine-based polymerization film can reduce wettability of the relevant part.

A third method for controlling wettability of the surface of the part on which no thin film is formed and wettability of the surface of the part on which a thin film is formed can be a method of applying silane coupling processing to the surface of the part on which no thin film is formed. Unlike the aforementioned first and second methods, applying silane coupling processing can also achieve operation and effects similar to those of the above described method. This third method is effective when the coating material (e.g., polymer hole injection layer formation material) is water-soluble.

According to this third method, when a polymer hole injection layer 14 is only formed on the transparent electrode 13 of the organic EL element 10 (surface of the pixel part 12) as in the above described case, the entire substrate is left standing in an HMDS atmosphere with the surface of the transparent electrode 13 covered with a mask for approximately 10 minutes and silane coupling processing is applied to the part other than the surface of the transparent electrode 13 or the entire substrate is left standing in an HMDS atmosphere without masking the entire substrate on which the transparent electrode 13 is formed and then the part other than the transparent electrode 13 (pixel part) is masked and only the surface of the transparent electrode 13 is subjected to UV ozone processing, and it is thereby possible to remove the silane compound on the surface of the transparent electrode 13.

The method according to the present invention controls wettability of the surface of the part on which a thin film is formed and the part on which no thin film is formed in the aforementioned wettability controlling step S1. However, specific numerical values of wettability of the surface of the part on which a thin film is formed and the part on which no thin film is formed are not particularly limited. That is, when a thin film material is applied to the entire surface in the thin film material application step S2 which will be described later, wettability of the surface of the part on which no thin film is formed only needs to be such a degree of wettability that the thin film material applied to the surface of the part on which no thin film is formed is naturally repelled and the thin film material only remains on the surface of the part on which a thin film is formed and the method can be selected according to the type or film thickness of the thin film material applied as appropriate or further according to the application method carried out in the thin film material application step S2 which will be described later.

For example, when a polymer hole injection layer is formed on the transparent electrode 13 (pixel part 12) of the aforementioned organic EL element 10, it is preferable to carry out the wettability controlling step S1 of controlling wettability of the part other than the transparent electrode 13 (pixel part 12) so that “a contact angle formed by the polymer hole injection layer formation material and the surface of the part other than the transparent electrode 13 (pixel part 12) becomes 45 degrees or more.” Here, this contact angle is a value measured according to JIS R3257 (Testing method of wettability of glass substrate).

According to the method of the present invention, the aforementioned wettability controlling step S1 is carried out first, followed by a thin film material application step S2.

This thin film material application step S2 is a step of actually forming a thin film by applying a thin film material to the surface whose wettability varies between the part on which a thin film is formed and the part on which no thin film is formed in the aforementioned wettability controlling step S1.

The method of the present invention is not particularly limited to the specific method in the thin film material application step S2, but it is possible to arbitrarily select various conventional publicly known methods, and for example, a printing method, spray method, or spin coat method, etc. can be used. Above all, the spin coat method is preferable because it can apply a thin film material uniformly. According to the conventional method, the spin coat method has difficulty in distinguishing the part on which a thin film is formed and the part on which no thin film is formed, and therefore this method is not suitable for the case where a polymer hole injection layer is formed only in the pixel part 12 of the organic EL element 10 shown in FIG. 1. However, according to the method of the present invention, the wettability controlling step S1 is performed as preprocessing prior to carrying out the thin film material application step S2, and therefore even if spin coat is applied to the entire surface regardless of the part on which a thin film is formed or the part on which no thin film is formed, the thin film material is adhered to only the part on which the thin film is formed. Furthermore, when a spray method is used as the thin film material application step S2, it is not necessary to use a mask as in the conventional case. Furthermore when a printing method is used, it is possible to form a thin film only in a predetermined part even if the printing accuracy is relatively low.

The thin film material used in the thin film material application step S2 is not particularly limited in the present invention, but it is possible to select and use any material other than the above described polymer hole injection layer material as appropriate.

When the organic EL element 10 is manufactured, as shown in FIG. 2, after completion of the thin film material application step S2, a baking step S3 of baking the applied polymer hole injection layer material and a film forming step S4 of forming other thin films (hole transport layer, light-emitting layer, electron transport layer, electrode (cathode)) are carried out sequentially.

In this way, since the method of forming a thin film when there exist a part on which a thin film is formed and a part on which no thin film is formed includes a wettability controlling step in which wettability of the surface of the part on which no thin film is formed is made lower than wettability of the surface of the other part (that is, the part on which a thin film is formed), even if a thin film material is applied to the entire surface without making any distinction between these parts, the thin film material applied to the relevant part is naturally repelled and moved to the part on which the thin film is formed. As a result, it is not necessary to use any mask when a thin film material is applied. Furthermore, when the thin film material is applied, there is no need to make any distinction between parts to which the thin film material is applied, and therefore it is possible to improve the application efficiency and also apply the thin film material uniformly.

Furthermore, adopting a step of forming a film containing fluorine for the surface of the part on which no thin film is formed or a step of fluorine replacement for the surface of the part on which no thin film is formed as the wettability controlling step makes it possible to control wettability efficiently.

Furthermore, by using such a method of forming a thin film to form a polymer hole injection layer in the pixel part of the organic EL element, that is, making the part on which a thin film is formed as the pixel part of the organic EL element and using the thin film formed as the polymer hole injection layer, it is possible to selectively form the polymer hole injection layer only in the pixel part and provide an organic EL element which causes no leakage current due to pinholes or insufficient coverage.

The present invention is not limited to the above described embodiments. The foregoing embodiments are to be considered as illustrative and any embodiments having substantially the same structure and same operation and effects as those of the technological thought described in the scope of the present invention being indicated by the appended claims are therefore intended to be embraced therein.

For example, the foregoing embodiment has explained the present invention with specific examples used to form a polymer hole injection layer in the pixel part of the organic EL element, but the present invention is not limited to this embodiment and it is also possible to apply the present invention to the formation of a resist of a color filter used for a liquid crystal display device. Furthermore, the foregoing embodiment has explained the case where the polymer hole injection layer 14 is formed on the transparent electrode 13 as a specific example, but the polymer hole injection layer 14 is not necessarily formed on the transparent electrode 13 only and may also be formed sticking out around the insulating film and pixel part depending on the type of the organic EL element 10.

Furthermore, the foregoing embodiment has explained fluorine replacement and formation of fluorine-based polymerization film as specific examples of a wettability controlling step, but the present invention is not limited to these examples and it is also possible to provide the surface with water repellency by forming, for example, a polyimide film instead of a fluorine-based polymerization film, then applying plasma processing to the surface of the polyimide film using a fluorine gas to control wettability with respect to the part on which the polyimide film is formed and the part on which no polyimide film is formed. In this case, it is also possible to apply etching to the polyimide film using a laser and oxygen plasma and remove the polyimide film after the completion of the thin film material application step.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2003-381755 filed on Nov. 11, 2003 including the specification, claims, drawings and summary is incorporated herein by reference in its entirety.

1. A method of forming a thin film in a case where there exist a part on which a thin film is formed and a part on which no thin film is formed, the method comprising a wettability controlling step of making wettability of the surface of the part on which no thin film is formed lower than wettability of the surface of the part on which the thin film is formed.

2. The method of forming a thin film according to claim 1, wherein the wettability controlling step is a step of forming a film containing fluorine on the surface of the part on which no thin film is formed.

3. The method of forming a thin film according to claim 1, wherein the wettability controlling step is a step of performing fluorine replacement on the surface of the part on which no thin film is formed.

4. The method of forming a thin film according to claim 1, wherein the wettability controlling step is a step of performing silane coupling processing on the surface of the part on which no thin film is formed.

5. The method of forming a thin film according to claim 1, wherein the part on which the thin film is formed is a pixel part of an organic EL element and the thin film formed is a polymer hole injection layer.
